(19) United States
(12) Patent Application Publication
(10) Pub. No.: US 2009/0146718 A1
(43) Pub. Date: Jun. 11, 2009

(54) DELAY CIRCUIT

(76) Inventor: Leaf Chen, Taipei (TW)

Correspondence Address: NORTH AMERICA INTELLECTUAL PROPERTY CORPORATION, P.O. BOX 506, MERRIFIELD, VA, 22116, US

(21) Appl. No.: 12/203,923

(22) Filed: Sep. 4, 2008

(30) Foreign Application Priority Data
Dec. 11, 2007 (TW) 096147225

(51) Int. Cl. H03H 11/26

(52) U.S. Cl. 327/288

(57) ABSTRACT

A delay circuit is disclosed for providing highly stable delay time in digital signal processing. The delay circuit includes a preliminary charging/discharging circuit, a signal processing circuit and an output circuit. The preliminary charging/discharging circuit performs charging and discharging operations based on a logic input signal for generating a voltage signal. The signal processing circuit performs signal processing on the voltage signal for generating a first delay signal and a second delay signal. The output circuit performs logic signal processing on the first and second delay signals for generating a logic output signal lagging behind the logic input signal by a delay time. The delay time is independent of any supply voltage. That is, even though the supply voltage is unstable, the delay circuit is capable of generating a stable logic output signal by performing a signal delay process on a logic input signal regardless of the unstable supply voltage.

### BACKGROUND OF THE INVENTION

1. Field of the Invention

The present invention relates to a delay circuit, and more particularly, to a delay circuit capable of providing a highly stable delay time unaffected by a drift of supply voltage.

2. Description of the Prior Art

Regarding a variety of application circuits operated under phase control mechanism, such as clock generators or RF transceivers, the accuracy of signal phase control for circuit operations is highly demanded. When a phase error occurs to the signal under processing, the circuit may not function properly. For instance, in the operation of a multi-phase clock generator, the accuracy of phase shift control for each generated clock features the generator performance. Any clock jitter caused by unstable phase shift may result in serious malfunction of phase-sensitive backend circuits, such as analog-to-digital converters or digital signal processors. The error of sampling time in the operation of an analog-to-digital converter may occur due to unstable phase shift of the sampling clock furnished by the clock generator. Also, higher bit error rate in the operation of a digital signal processor usually occurs as a consequence of clock jitter due to unstable phase control of the system clock provided by the clock generator. Accordingly, the layout designs for phase-sensitive circuits are normally set forth under careful consideration of phase delay with respect to routing path. However, when the drift of the supply voltage furnished to a prior-art delay circuit occurs, the prior-art delay circuit is unable to provide accurate phase delay control on the signal under processing, and an auxiliary mechanism is required to compensate unstable phase shift caused by the drift of the supply voltage.

In general, the prior-art delay circuit performs a delay process on the received signal via the charging/discharging operation of capacitive elements. Please refer to FIG. 1, which is a circuit diagram schematically showing a prior-art delay circuit 100. The delay circuit 100 comprises a preliminary charging/discharging circuit 105 and an inverter 190. The preliminary charging/discharging circuit 105 comprises a first current source 110, a second current source 112, a first control switch 120, a second control switch 122, and a capacitor 130. The inverter 190 includes a P-channel metal-oxide-semiconductor (MOS) field effect transistor 180 and an N-channel MOS field effect transistor 182. The delay circuit 100 is powered between a first supply voltage Vdd and a second supply voltage Vss. The first control switch 120 and the second control switch 122 are turned on/off in response to a logic input signal Sin. The first current source 110 provides a current I1 for charging the capacitor 130 when the first control switch 120 is turned on. The second current source 112 provides a current I2 for discharging the capacitor 130 when the second control switch 122 is turned on. The inverter 190 performs an inverting process on the voltage signal Vc of the capacitor 130 for generating a logic output signal Sout lagging the logic input signal Sin by a predetermined delay time.

When a voltage drift occurs to the first supply voltage Vdd or the second supply voltage Vss, the input transition voltage of the inverter 190 is changed accordingly, and hence the delay-related voltage swing range regarding the charging/discharging operation of the capacitor 130 is also changed. That is, the voltage drift of the first supply voltage Vdd or the second supply voltage Vss has an effect on the phase delay of the logic output signal Sout with respect to the logic input signal Sin. As a result, the phase shift operation of the delay circuit 100 is unstable when the first supply voltage Vdd or the second supply voltage Vss is unstable.

Please refer to FIG. 2, which is a circuit diagram schematically showing another prior-art delay circuit 200. The delay circuit 200 comprises a preliminary charging/discharging circuit 205 and a compare circuit 290. The preliminary charging/discharging circuit 205 generates the voltage signal Vc based on the logic input signal Sin. As shown in FIG. 2, the circuit structure of the preliminary charging/discharging circuit 205 is identical to the circuit structure of the preliminary charging/discharging circuit 105, and for the sake of brevity, the description on the preliminary charging/discharging circuit 205 is omitted. The compare circuit 290 comprises a comparator 295 and a voltage divider. The voltage divider includes two resistors 291 and 292. The resistors 291 and 292 are series-connected between the first supply voltage Vdd and the second supply voltage Vss for providing a reference voltage Vr. The comparator 295 generates the logic output signal Sout by comparing the voltage signal Vc with the reference voltage Vr.

The input transition voltage of the compare circuit 290 is set to be the reference voltage Vr regardless of rising or falling of the voltage signal Vc. However, the voltage drift of the first supply voltage Vdd or the second supply voltage Vss also has an effect on the reference voltage Vr. In view of that, the phase shift operation of the delay circuit 200 is also unstable when the first supply voltage Vdd or the second supply voltage Vss is unstable. Besides, extra power consumption of the resistors 291 and 292 causes another negative aspect. Higher resistance of the resistors 291 and 292 may reduce power consumption, but it is paid by larger die area required for the layout of the resistors 291 and 292, which results in lower circuit integrity and higher production cost.

### SUMMARY OF THE INVENTION

In accordance with an embodiment of the present invention, a delay circuit capable of providing highly stable delay time is disclosed. The delay circuit comprises a preliminary charging/discharging circuit, a signal processing circuit, and an output circuit.

The preliminary charging/discharging circuit comprises an input end for receiving a logic input signal and an output end for outputting a voltage signal. The preliminary charging/discharging circuit is utilized to perform charging/discharging operations on the logic input signal for generating the voltage signal. The signal processing circuit is coupled to the output end of the preliminary charging/discharging circuit for generating a first delayed signal and a second delayed signal based on the voltage signal. The signal processing circuit comprises a first current source, a first transistor, a second current source, and a second transistor. The first current source comprises a first end for receiving a first supply voltage and a second end. The first transistor comprises a first end for receiving a second supply voltage, a second end coupled to the second end of the first current source, and a control end coupled to the output end of the preliminary charging/discharging circuit for receiving the voltage signal. Besides, the second end of the first transistor is utilized for outputting the first delayed signal. The second current source comprises a first end for receiving the second supply voltage and a second end. The second transistor comprises a first end for receiving the first supply voltage, a second end coupled to the second end of the second current source, and a control end coupled to the output end of the preliminary charging/discharging circuit for receiving the voltage signal. Besides, the second end of the second transistor is utilized for outputting the second delayed signal. The output circuit comprises a first input end coupled to the second end of the first transistor for receiving the first delayed signal, a second input end coupled to the second end of the second transistor for receiving the second delayed signal, a third input end for receiving the logic input signal, and an output end for outputting a logic output signal. The output circuit is utilized for generating the logic output signal based on the first delayed signal, the second delayed signal, and the logic input signal.

In accordance with another embodiment of the present invention, a delay circuit capable of providing highly stable delay time is disclosed. The delay circuit comprises a preliminary charging/discharging circuit, a signal processing circuit, and an output circuit.

The preliminary charging/discharging circuit comprises an input end for receiving a logic input signal and an output end for outputting a voltage signal. The preliminary charging/discharging circuit is utilized to perform charging/discharging operations on the logic input signal for generating the voltage signal. The signal processing circuit is coupled to the output end of the preliminary charging/discharging circuit for generating a first delayed signal and a second delayed signal based on the voltage signal. The signal processing circuit comprises a first current source, a first transistor, a second current source, and a second transistor. The first current source comprises a first end for receiving a first supply voltage and a second end. The first transistor comprises a first end for receiving a second supply voltage, a second end coupled to the second end of the first current source, and a control end coupled to the output end of the preliminary charging/discharging circuit for receiving the voltage signal. Besides, the second end of the first transistor is utilized for outputting the first delayed signal. The second current source comprises a first end for receiving the second supply voltage and a second end. The second transistor comprises a first end for receiving the first supply voltage, a second end coupled to the second end of the second current source, and a control end coupled to the output end of the preliminary charging/discharging circuit for receiving the voltage signal. Besides, the second end of the second transistor is utilized for outputting the second delayed signal. The output circuit comprises a first input end coupled to the second end of the first transistor for receiving the first delayed signal, a second input end coupled to the second end of the second transistor for receiving the second delayed signal, and an output end for outputting a logic output signal. The output circuit is utilized for generating the logic output signal based on the first delayed signal and the second delayed signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a circuit diagram schematically showing a prior-art delay circuit.

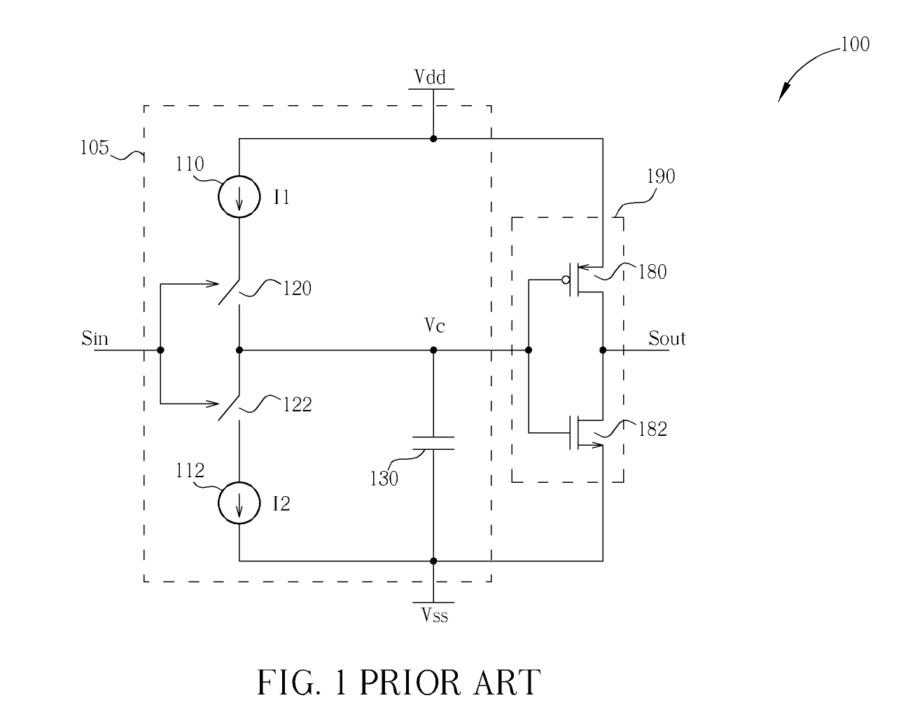

FIG. 2 is a circuit diagram schematically showing another prior-art delay circuit.

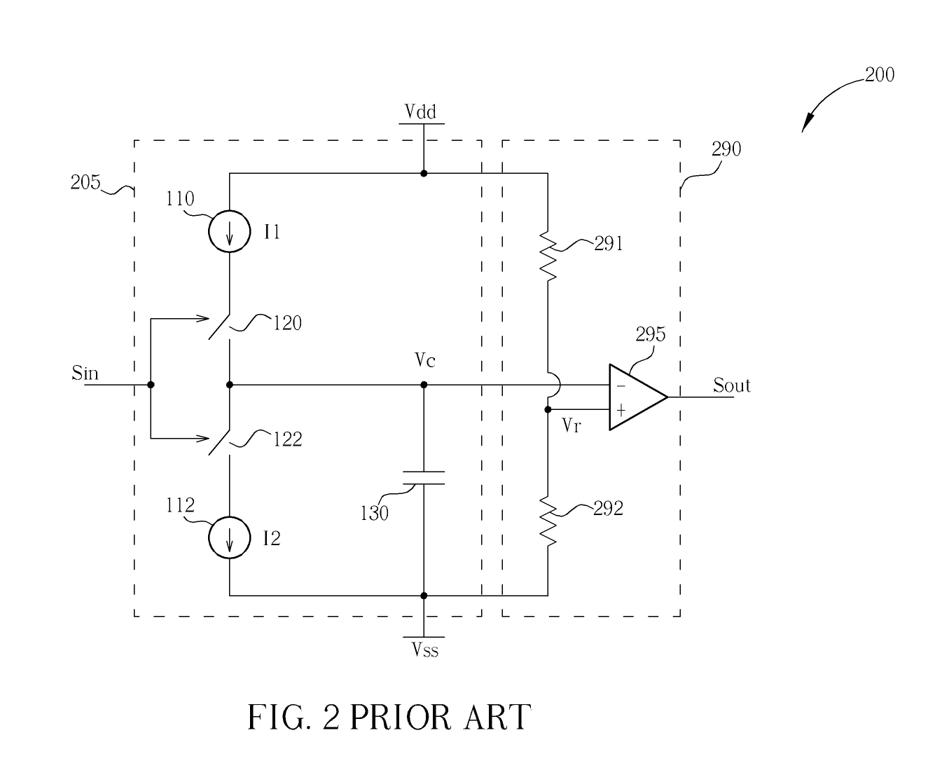

FIG. 3 is a circuit diagram schematically showing a delay circuit in accordance with a first embodiment of the present invention.

FIG. 4 shows the related signal waveforms regarding the operation of the delay circuit in FIG. 3, having time along the abscissa.

FIG. 5 is a circuit diagram schematically showing a delay circuit in accordance with a second embodiment of the present invention.

FIG. 6 is a circuit diagram schematically showing a delay circuit in accordance with a third embodiment of the present invention.

FIG. 7 is a circuit diagram schematically showing a delay circuit in accordance with a fourth embodiment of the present invention.

### DETAILED DESCRIPTION

Hereinafter, preferred embodiments of the present invention will be described in detail with reference to the accompanying drawings. Here, it is to be noted that the present invention is not limited thereto.

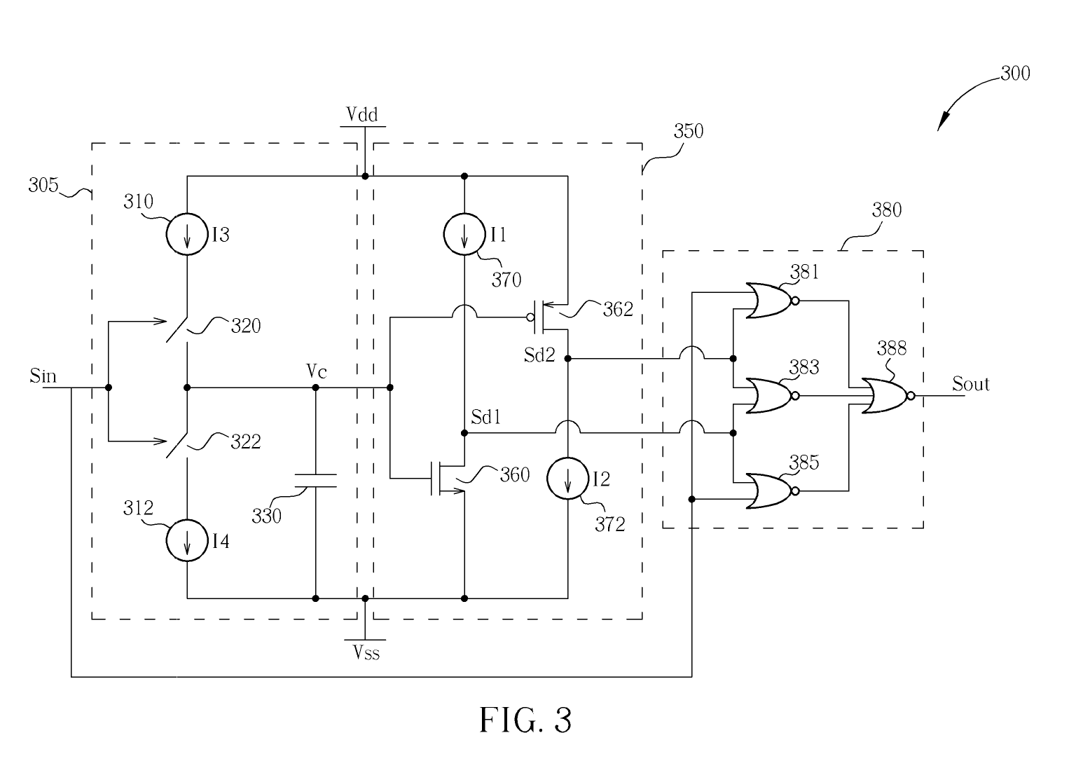

Please refer to FIG. 3, which is a circuit diagram schematically showing a delay circuit 300 in accordance with a first embodiment of the present invention. The delay circuit 300 comprises a preliminary charging/discharging circuit 305, a signal processing circuit 350, and an output circuit 380. The signal processing circuit 350 comprises a first current source 370, a first transistor 360, a second current source 372, and a second transistor 362. The preliminary charging/discharging circuit 305 comprises a third current source 310, a first control switch 320, a fourth current source 312, a second control switch 322, and a capacitor 330. The output circuit 380 comprises a first NOR gate 381, a second NOR gate 383, a third NOR gate 385, and a fourth NOR gate 388.

The third current source 310 comprises a first end for receiving a first supply voltage Vdd and a second end for providing a current I3. The first control switch 320 comprises a first end, a second end, and a control end. The first end of the first control switch 320 is coupled to the second end of the third current source 310. The second end of the first control switch 320 functions as an outlet for forwarding the current I3. The electrical connection between the first and second ends of the first control switch 320 is controlled by a logic input signal Sin furnished to the control end of the first control switch 320.

The fourth current source 312 comprises a first end for receiving a second supply voltage Vss and a second end for providing a current I4. The second supply voltage Vss can be a ground voltage. The second control switch 322 comprises a first end, a second end, and a control end. The first end of the second control switch 322 is coupled to the second end of the fourth current source 312. The second end of the second control switch 322 is coupled to the second end of the first control switch 320 and functions as an inlet for sinking the current I4. The electrical connection between the first and second ends of the second control switch 322 is controlled by the logic input signal Sin furnished to the control end of the second control switch 322. The first control switch 320 and the second control switch 322 can be electronic relays, MOS field effect transistors, or bipolar junction transistors.

The capacitor 330 comprises a first end coupled to the second ends of the first control switch 320 and the second control switch 322, and a second end for receiving the second supply voltage Vss. The voltage signal Vc is generated at the first end of the capacitor 330. When the logic input signal Sin having low-level voltage is applied to the control ends of the first control switch 320 and the second control switch 322, the first control switch 320 is turned on and the second control switch 322 is turned off so that the voltage signal Vc can be pulled up to the first supply voltage Vdd via a charging process based on the current I3 provided by the third current source 310. When the logic input signal Sin having high-level voltage is applied to the control ends of the first control switch 320 and the second control switch 322, the first control switch 320 is turned off and the second control switch 322 is turned on so that the voltage signal Vc can be pulled down to the second supply voltage Vss via a discharging process based on the current I4 provided by the fourth current source 312.

The first current source 370 comprises a first end for receiving the first supply voltage Vdd and a second end for providing a current I1. The first transistor 360 comprises a first end, a second end, and a control end. The first end of the first transistor 360 is utilized for receiving the second supply voltage Vss. The second end of the first transistor 360 is coupled to the second end of the first current source 370. The control end of the first transistor 360 is coupled to the first end of the capacitor 330 for receiving the voltage signal Vc. Besides, the second end of the first transistor 360 is utilized for outputting a first delayed signal Sd1. The first transistor 360 is an N-channel MOS field effect transistor or an N-channel junction field effect transistor.

The second current source 372 comprises a first end for receiving the second supply voltage Vss and a second end for providing a current I2. The second transistor 362 comprises a first end, a second end, and a control end. The first end of the second transistor 362 is utilized for receiving the first supply voltage Vdd. The second end of the second transistor 362 is coupled to the second end of the second current source 372. The control end of the second transistor 362 is coupled to the first end of the capacitor 330 for receiving the voltage signal Vc. Besides, the second end of the second transistor 362 is utilized for outputting a second delayed signal Sd2. The second transistor 362 is a P-channel MOS field effect transistor or a P-channel junction field effect transistor.

The first NOR gate 381 comprises a first input end for receiving the logic input signal Sin, a second input end coupled to the second end of the second transistor 362 for receiving the second delayed signal Sd2, and an output end for outputting a first signal generated by performing a NOR operation on the logic input signal Sin and the second delayed signal Sd2. The second NOR gate 383 comprises a first input end coupled to the second end of the second transistor 362 for receiving the second delayed signal Sd2, a second input end coupled to the second end of the first transistor 360 for receiving the first delayed signal Sd1, and an output end for outputting a second signal generated by performing a NOR operation on the first delayed signal Sd1 and the second delayed signal Sd2.

The third NOR gate 385 comprises a first input end for receiving the logic input signal Sin, a second input end coupled to the second end of the first transistor 360 for receiving the first delayed signal Sd1, and an output end for outputting a third signal generated by performing a NOR operation on the logic input signal Sin and the first delayed signal Sd1. The fourth NOR gate 388 comprises a first input end coupled to the output end of the first NOR gate 381 for receiving the first signal, a second input end coupled to the output end of the second NOR gate 383 for receiving the second signal, a third input end coupled to the output end of the third NOR gate 385 for receiving the third signal, and an output end for outputting a logic output signal Sout generated by performing a NOR operation on the first, second and third signals.

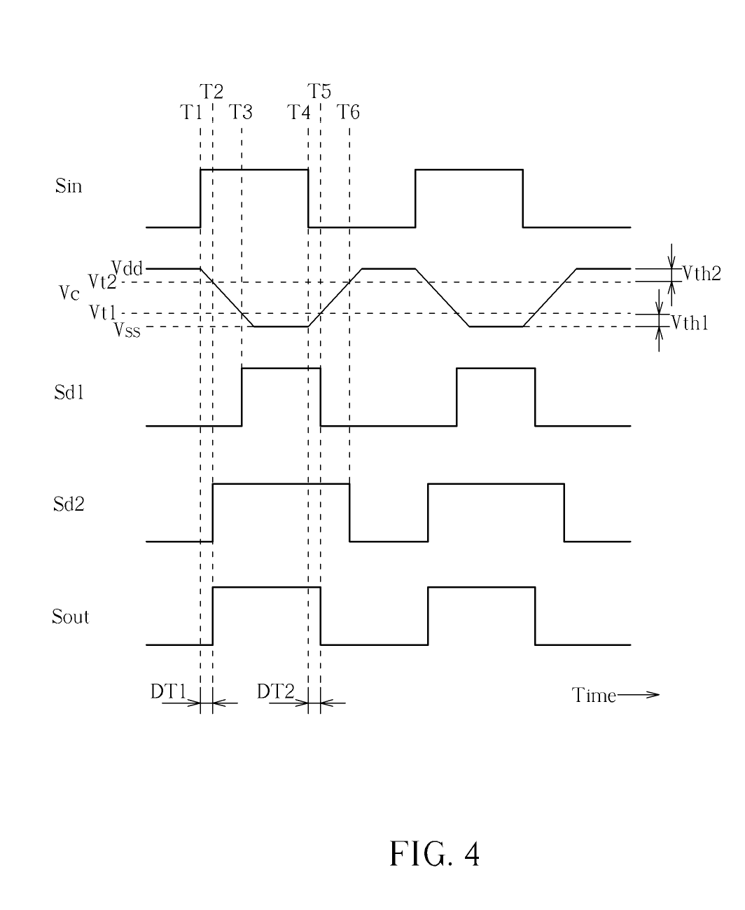

Please refer to FIG. 4, which shows the related signal waveforms regarding the operation of the delay circuit 300 in FIG. 3, having time along the abscissa. The signal waveforms in FIG. 4, from top to bottom, are the logic input signal Sin, the voltage signal Vc, the first delayed signal Sd1, the second delayed signal Sd2, and the logic output signal Sout. The following description details the operation of the delay circuit 300 based on the waveforms shown in FIG. 4.

When the logic input signal Sin switches from low-level voltage to high-level voltage at time T1, the first control switch 320 is turned off and the second control switch 322 is turned on, and therefore the voltage signal Vc is decreasing from the first supply voltage Vdd downwards eventually to the second supply voltage Vss by discharging the capacitor 330 with the aid of the current I4 provided by the fourth current source 312. When the voltage signal Vc is lowered to a second transition voltage Vt2 at time T2, the voltage drop across the control end and the first end of the second transistor 362 is then reaching the second threshold voltage Vth2 of the second transistor 362. Accordingly, the second transistor 362 is switched from off-state to on-state so that the second delayed signal Sd2 is shifted from the low-level voltage to the high-level voltage at time T2. When the voltage signal Vc is further lowered to a first transition voltage Vt1 at time T3, the voltage drop across the control end and the first end of the first transistor 360 is then reaching the first threshold voltage Vth1 of the first transistor 360. Accordingly, the first transistor 360 is switched from on-state to off-state so that the first delayed signal Sd1 is shifted from the low-level voltage to the high-level voltage at time T3.

When the logic input signal Sin switches from high-level voltage to low-level voltage at time T4, the first control switch 320 is turned on and the second control switch 322 is turned off, and therefore the voltage signal Vc is increasing from the second supply voltage Vss upwards eventually to the first supply voltage Vdd by charging the capacitor 330 with the aid of the current I3 provided by the third current source 310. When the voltage signal Vc is raised to the first transition voltage Vt1 at time T5, the voltage drop across the control end and the first end of the first transistor 360 is then reaching the first threshold voltage Vth1. Accordingly, the first transistor 360 is switched from off-state to on-state so that the first delayed signal Sd1 is shifted from high-level voltage to low-level voltage at time T5. When the voltage signal Vc is further raised to the second transition voltage Vt2 at time T6, the voltage drop across the control end and the first end of the second transistor 362 is then reaching the second threshold voltage Vth2. Accordingly, the second transistor 362 is switched from on-state to off-state so that the second delayed signal Sd2 is shifted from high-level voltage to low-level voltage at time T6.

The logic output signal Sout shown in FIG. 4 is generated by the output circuit 380 through performing the logic operation on the first delayed signal Sd1, the second delayed signal Sd2, and the logic input signal Sin. The pulse fore-end of the logic output signal Sout is lagging behind the pulse fore-end of the logic input signal Sin by a rising-edge delay time DT1. The pulse rear-end of the logic output signal Sout is lagging behind the pulse rear-end of the logic input signal Sin by a falling-edge delay time DT2. The relationships concerning the rising-edge delay time DT1 and the falling-edge delay time DT2 can be expressed as the following formulas.

$$\begin{matrix}DT 1 = \frac{C \times Vth 2}{Ic 4} & Formula ( 1 ) \\ DT 2 = \frac{C \times Vth 1}{Ic 3} & Formula ( 2 )\end{matrix}$$

In the Formulas (1) and (2), C represents the capacitance of the capacitor 330, Ic3 represents the current value of the current I3, and Ic4 represents the current value of the current I4. In accordance with the Formula (1), the rising-edge delay time DT1 is determined by the current value Ic4, the second threshold voltage Vth2, and the capacitance C. Also, in accordance with the Formula (2), the falling-edge delay time DT2 is determined by the current value Ic3, the first threshold voltage Vth1, and the capacitance C. That is, all the parameters in the Formulas (1) and (2) are independent of the first supply voltage Vdd and the second supply voltage Vss. Therefore, the drift of the first supply voltage Vdd or the second supply voltage Vss has no effect on the rising-edge delay time DT1 and the falling-edge delay time DT2. As a result, the delay circuit 300 is able to generate the logic output signal Sout without phase jitter based on the logic input signal Sin regardless of any unstable supply voltage.

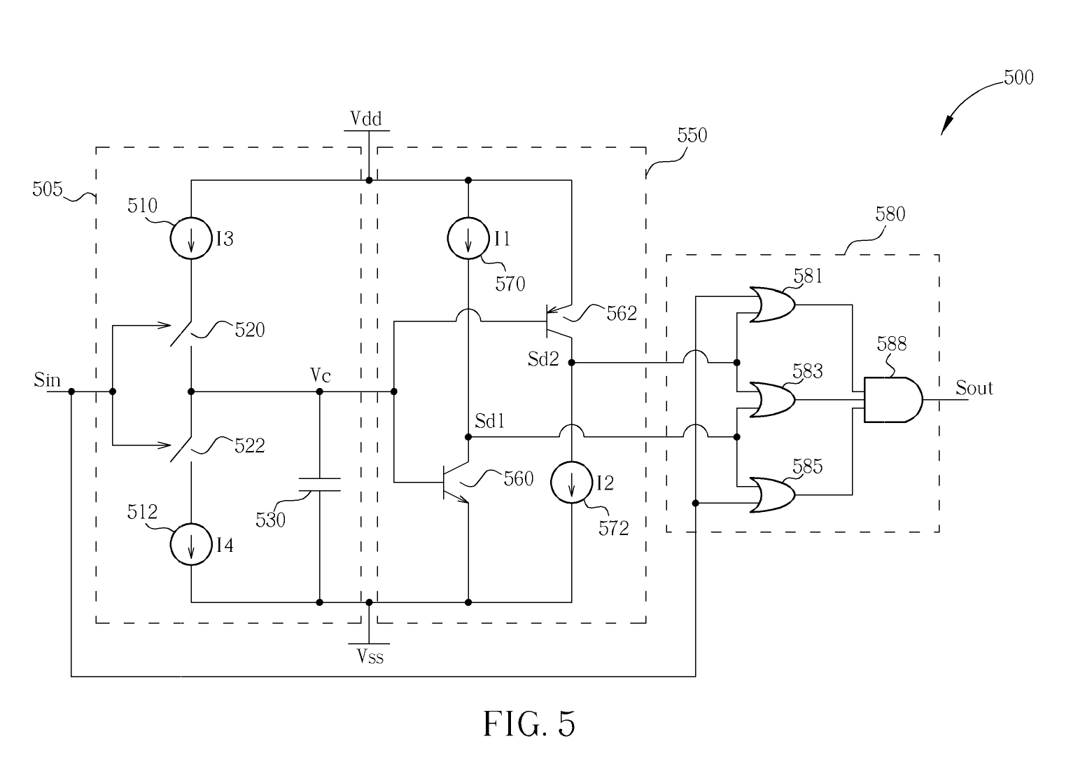

Please refer to FIG. 5, which is a circuit diagram schematically showing a delay circuit 500 in accordance with a second embodiment of the present invention. The delay circuit 500 comprises a preliminary charging/discharging circuit 505, a signal processing circuit 550, and an output circuit 580. The signal processing circuit 550 comprises a first current source 570, a first transistor 560, a second current source 572, and a second transistor 562. The preliminary charging/discharging circuit 505 comprises a third current source 510, a first control switch 520, a fourth current source 512, a second control switch 522, and a capacitor 530. The output circuit 580 comprises a first OR gate 581, a second OR gate 583, a third OR gate 585, and an AND gate 588.

The circuit structure of the preliminary charging/discharging circuit 505 is identical to the circuit structure of the preliminary charging/discharging circuit 305, and for the sake of brevity, further similar description on the component arrangements of the preliminary charging/discharging circuit 505 is omitted. The first current source 570 comprises a first end for receiving the first supply voltage Vdd and a second end for providing a current I1. The first transistor 560 comprises a first end for receiving the second supply voltage Vss, a second end coupled to the second end of the first current source 570, and a control end coupled to the capacitor 530 for receiving a voltage signal Vc. Besides, the second end of the first transistor 560 is utilized for outputting a first delayed signal Sd1. The first transistor 560 can be an NPN bipolar junction transistor.

The second current source 572 comprises a first end for receiving the second supply voltage Vss and a second end for providing a current I2. The second transistor 562 comprises a first end for receiving the first supply voltage Vdd, a second end coupled to the second end of the second current source 572, and a control end coupled to the capacitor 530 for receiving the voltage signal Vc. Besides, the second end of the second transistor 562 is utilized for outputting a second delayed signal Sd2. The second transistor 562 can be a PNP bipolar junction transistor.

The first OR gate comprises a first input end for receiving an input logic signal Sin, a second input end coupled to the second end of the second transistor 562 for receiving the second delayed signal Sd2, and an output end for outputting a first signal generated by performing an OR operation on the logic input signal Sin and the second delayed signal Sd2. The second OR gate 583 comprises a first input end coupled to the second end of the second transistor 562 for receiving the second delayed signal Sd2, a second input end coupled to the second end of the first transistor 560 for receiving the first delayed signal Sd1, and an output end for outputting a second signal generated by performing an OR operation on the first delayed signal Sd1 and the second delayed signal Sd2.

The third OR gate 585 comprises a first input end for receiving an input logic signal Sin, a second input end coupled to the second end of the first transistor 560 for receiving the first delayed signal Sd1, and an output end for outputting a third signal generated by performing an OR operation on the logic input signal Sin and the first delayed signal Sd1. The AND gate 588 comprises a first input end coupled to the output end of the first OR gate 581 for receiving the first signal, a second input end coupled to the output end of the second OR gate 583 for receiving the second signal, a third input end coupled to the output end of the third OR gate 585 for receiving the third signal, and an output end for outputting a logic output signal Sout generated by performing an AND operation on the first, second and third signals.

The signal waveforms of the logic input signal Sin, the voltage signal Vc, the first delayed signal Sd1, the second delayed signal Sd2, and the logic output signal Sout regarding the operation of the delay circuit 500 are identical to the signal waveforms shown in FIG. 4, and for the sake of brevity, further similar discussion on the operation of the delay circuit 500 is omitted.

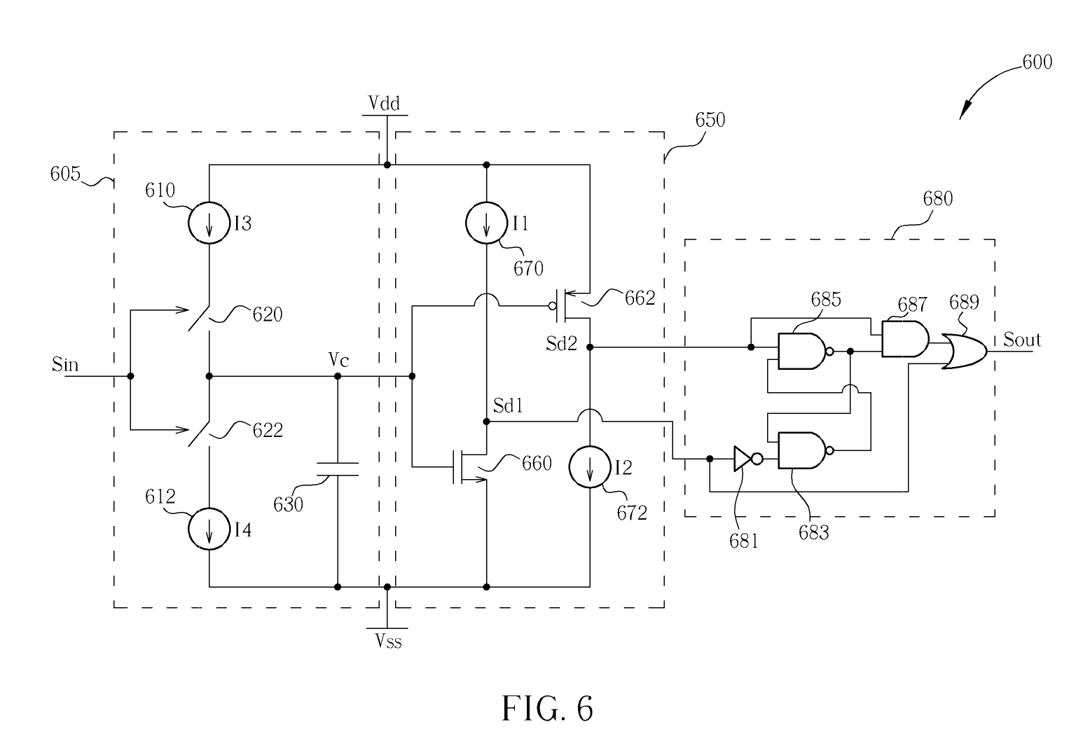

Please refer to FIG. 6, which is a circuit diagram schematically showing a delay circuit 600 in accordance with a third embodiment of the present invention. The delay circuit 600 comprises a preliminary charging/discharging circuit 605, a signal processing circuit 650, and an output circuit 680. The signal processing circuit 650 comprises a first current source 670, a first transistor 660, a second current source 672, and a second transistor 662. The preliminary charging/discharging circuit 605 comprises a third current source 610, a first control switch 620, a fourth current source 612, a second control switch 622, and a capacitor 630. The output circuit 680 comprises an inverter 681, a first NAND gate 683, a second NAND gate 685, an AND gate 687, and an OR gate 689.

The circuit structures of the preliminary charging/discharging circuit 605 and the signal processing circuit 650 are identical to the circuit structures of the preliminary charging/discharging circuit 305 and the signal processing circuit 350, and for the sake of brevity, the description on the component arrangements of the preliminary charging/discharging circuit 605 and the signal processing circuit 650 is omitted. The inverter 681 comprises an input end coupled to the first transistor 660 for receiving a first delayed signal Sd1 and an output end for outputting a first signal generated by performing an inverting operation on the first delayed signal Sd1. The first NAND gate 683 comprises a first input end, a second input end, and an output end. The first input end of the first NAND gate 683 is coupled to the output end of the inverter 681 for receiving the first signal. The second NAND gate 685 comprises a first input end coupled to the second transistor 662 for receiving a second delayed signal Sd2, a second input end coupled to the output end of the first NAND gate 683, and an output end coupled to the second input end of the first NAND gate 683.

The second NAND gate 685 in conjunction with the first NAND gate 683 functions as an RS flip-flop for generating a second signal based on the second delayed signal Sd2 and the first signal. The second signal is outputted from the output end of the second NAND gate 685. The AND gate 687 comprises a first input end coupled to the second transistor 662 for receiving the second delayed signal Sd2, a second input end coupled to the output end of the second NAND gate 685 for receiving the second signal, and an output end for outputting a third signal generated by performing an AND operation on the second delayed signal Sd2 and the second signal. The OR gate 689 comprises a first input end coupled to the output end of the AND gate 687 for receiving the third signal, a second input end coupled to the first transistor 660 for receiving the first delayed signal Sd1, and an output end for outputting a logic output signal Sout generated by performing an OR operation on the first delayed signal Sd1 and the third signal.

The signal waveforms of the logic input signal Sin, the voltage signal Vc, the first delayed signal Sd1, the second delayed signal Sd2, and the logic output signal Sout regarding the operation of the delay circuit 600 are identical to the signal waveforms shown in FIG. 4, and for the sake of brevity, further similar discussion on the operation of the delay circuit 600 is omitted.

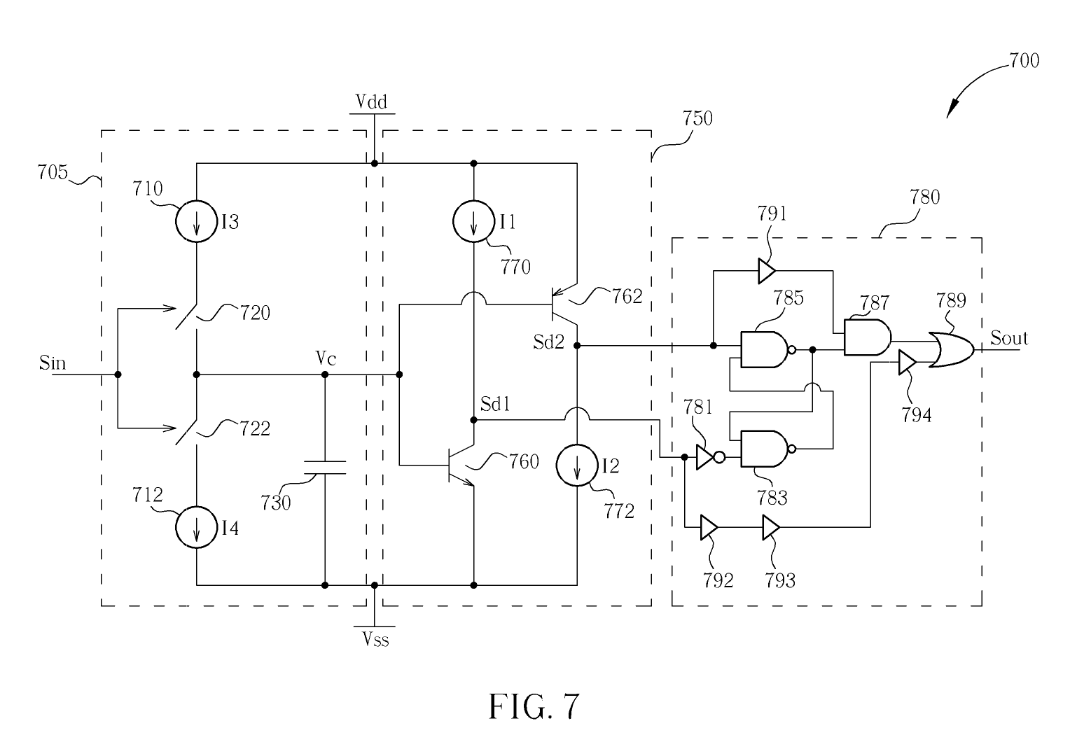

Please refer to FIG. 7, which is a circuit diagram schematically showing a delay circuit 700 in accordance with a fourth embodiment of the present invention. The delay circuit 700 comprises a preliminary charging/discharging circuit 705, a signal processing circuit 750, and an output circuit 780. The signal processing circuit 750 comprises a first current source 770, a first transistor 760, a second current source 772, and a second transistor 762. The preliminary charging/discharging circuit 705 comprises a third current source 710, a first control switch 720, a fourth current source 712, a second control switch 722, and a capacitor 730. The output circuit 780 comprises an inverter 781, a first NAND gate 783, a second NAND gate 785, an AND gate 787, an OR gate 789, and a plurality of buffers 791-794.

The circuit structures of the preliminary charging/discharging circuit 705 and the signal processing circuit 750 are identical to the circuit structures of the preliminary charging/discharging circuit 505 and the signal processing circuit 550, and for the sake of brevity, the description on the component arrangements of the preliminary charging/discharging circuit 705 and the signal processing circuit 750 is omitted. The buffer 791 is coupled between the second transistor 762 and the AND gate 787. The buffers 792-794 are series-connected between the first transistor 760 and the OR gate 789. The other component arrangements of the output circuit 780 are identical to the component arrangements of the output circuit 680. The signal waveforms of the logic input signal Sin, the voltage signal Vc, the first delayed signal Sd1, the second delayed signal Sd2, and the logic output signal Sout regarding the operation of the delay circuit 700 are identical to the signal waveforms shown in FIG. 4, and for the sake of brevity, further similar discussion on the operation of the delay circuit 700 is omitted.

In summary, the delay circuit of the present invention determines the signal-related delay times based on the threshold voltages of transistors, the capacitance of charging/discharging capacitor, and the current values of current sources. That is, the drift of any supply voltage has no effect on the signal-related delay times. Consequently, the delay circuit of the present invention is able to generate a stable logic output signal without phase jitter based on a logic input signal regardless of any unstable supply voltage.

The present invention is by no means limited to the embodiments as described above by referring to the accompanying drawings, which may be modified and altered in a variety of different ways without departing from the scope of the present invention. Thus, it should be understood by those skilled in the art that various modifications, combinations, sub-combinations and alternations might occur depending on design requirements and other factors insofar as they are within the scope of the appended claims or the equivalents thereof.

What is claimed is:

1. A delay circuit comprising:
a preliminary charging/discharging circuit comprising an input end for receiving a logic input signal and an output end for outputting a voltage signal, the preliminary charging/discharging circuit being utilized to perform charging/discharging operations on the logic input signal for generating the voltage signal;
a signal processing circuit coupled to the output end of the preliminary charging/discharging circuit for receiving the voltage signal, the signal processing circuit being utilized for generating a first delayed signal and a second delayed signal based on the voltage signal, the signal processing circuit comprising:
a first current source comprising a first end for receiving a first supply voltage and a second end;
a first transistor comprising a first end for receiving a second supply voltage, a second end coupled to the second end of the first current source, and a control end coupled to the output end of the preliminary charging/discharging circuit for receiving the voltage signal, wherein the second end of the first transistor is utilized for outputting the first delayed signal;
a second current source comprising a first end for receiving the second supply voltage and a second end; and
a second transistor comprising a first end for receiving the first supply voltage, a second end coupled to the second end of the second current source, and a control end coupled to the output end of the preliminary charging/discharging circuit for receiving the voltage signal, wherein the second end of the second transistor is utilized for outputting the second delayed signal; and
an output circuit comprising a first input end coupled to the second end of the first transistor for receiving the first delayed signal, a second input end coupled to the second end of the second transistor for receiving the second delayed signal, a third input end for receiving the logic input signal, and an output end for outputting a logic output signal, the output circuit being utilized for generating the logic output signal based on the first delayed signal, the second delayed signal, and the logic input signal.

2. The delay circuit of claim 1, wherein the preliminary charging/discharging circuit comprises:
a third current source comprising a first end for receiving the first supply voltage and a second end;
a first control switch comprising a first end coupled to the second end of the third current source, a control end for receiving the logic input signal, and a second end;
a fourth current source comprising a first end for receiving the second supply voltage and a second end;
a second control switch comprising a first end coupled to the second end of the fourth current source, a control end for receiving the logic input signal, and a second end coupled to the second end of the first control switch; and
a capacitor comprising a first end coupled to the second end of the first control switch for outputting the voltage signal and a second end for receiving the second supply voltage.

3. The delay circuit of claim 1, wherein the output circuit comprises:
a first NOR gate comprising a first input end for receiving the logic input signal, a second input end coupled to the second end of the second transistor for receiving the second delayed signal, and an output end;
a second NOR gate comprising a first input end coupled to the second end of the second transistor for receiving the second delayed signal, a second input end coupled to the second end of the first transistor for receiving the first delayed signal, and an output end;
a third NOR gate comprising a first input end for receiving the logic input signal, a second input end coupled to the second end of the first transistor for receiving the first delayed signal, and an output end; and
a fourth NOR gate comprising a first input end coupled to the output end of the first NOR gate, a second input end coupled to the output end of the second NOR gate, a third input end coupled to the output end of the third NOR gate, and an output end for outputting the logic output signal.

4. The delay circuit of claim 1, wherein the output circuit comprises:
a first OR gate comprising a first input end for receiving the logic input signal, a second input end coupled to the second end of the second transistor for receiving the second delayed signal, and an output end;
a second OR gate comprising a first input end coupled to the second end of the second transistor for receiving the second delayed signal, a second input end coupled to the second end of the first transistor for receiving the first delayed signal, and an output end;
a third OR gate comprising a first input end for receiving the logic input signal, a second input end coupled to the second end of the first transistor for receiving the first delayed signal, and an output end; and
an AND gate comprising a first input end coupled to the output end of the first OR gate, a second input end coupled to the output end of the second OR gate, a third input end coupled to the output end of the third OR gate, and an output end for outputting the logic output signal.

5. The delay circuit of claim 1, wherein the first transistor is an N-channel MOS field effect transistor, an N-channel junction field effect transistor, or an NPN bipolar junction transistor.

6. The delay circuit of claim 1, wherein the second transistor is a P-channel MOS field effect transistor, a P-channel junction field effect transistor, or a PNP bipolar junction transistor.

7. The delay circuit of claim 1, wherein the signal processing circuit outputs the first delayed signal having high-level voltage and the second delayed signal having high-level voltage when the voltage signal is less than a first transition voltage, the signal processing circuit outputs the first delayed signal having low-level voltage and the second delayed signal having low-level voltage when the voltage signal is greater than a second transition voltage, and the signal processing circuit outputs the first delayed signal having low-level voltage and the second delayed signal having high-level voltage when the voltage signal is falling into a voltage range between the first transition voltage and the second transition voltage.

8. The delay circuit of claim 7, wherein the first transition voltage is a summation of the second supply voltage and a threshold voltage of the first transistor.

9. The delay circuit of claim 7, wherein the second transition voltage is a difference of the first supply voltage and a threshold voltage of the second transistor.

10. The delay circuit of claim 1, wherein the second supply voltage is a ground voltage.

11. A delay circuit comprising:
a preliminary charging/discharging circuit comprising an input end for receiving a logic input signal and an output end for outputting a voltage signal, the preliminary charging/discharging circuit being utilized to perform charging/discharging operations on the logic input signal for generating the voltage signal;
a signal processing circuit coupled to the output end of the preliminary charging/discharging circuit for receiving the voltage signal, the signal processing circuit being utilized for generating a first delayed signal and a second delayed signal based on the voltage signal, the signal processing circuit comprising:
a first current source comprising a first end for receiving a first supply voltage and a second end;
a first transistor comprising a first end for receiving a second supply voltage, a second end coupled to the second end of the first current source, and a control end coupled to the output end of the preliminary charging/discharging circuit for receiving the voltage signal, wherein the second end of the first transistor is utilized for outputting the first delayed signal;
a second current source comprising a first end for receiving the second supply voltage and a second end; and
a second transistor comprising a first end for receiving the first supply voltage, a second end coupled to the second end of the second current source, and a control end coupled to the output end of the preliminary charging/discharging circuit for receiving the voltage signal, wherein the second end of the second transistor is utilized for outputting the second delayed signal; and
an output circuit comprising a first input end coupled to the second end of the first transistor for receiving the first delayed signal, a second input end coupled to the second end of the second transistor for receiving the second delayed signal, and an output end for outputting a logic output signal, the output circuit being utilized for generating the logic output signal based on the first delayed signal and the second delayed signal.

12. The delay circuit of claim 11, wherein the preliminary charging/discharging circuit comprises:
a third current source comprising a first end for receiving the first supply voltage and a second end;
a first control switch comprising a first end coupled to the second end of the third current source, a control end for receiving the logic input signal, and a second end;
a fourth current source comprising a first end for receiving the second supply voltage and a second end;
a second control switch comprising a first end coupled to the second end of the fourth current source, a control end for receiving the logic input signal, and a second end coupled to the second end of the first control switch; and
a capacitor comprising a first end coupled to the second end of the first control switch for outputting the voltage signal and a second end for receiving the second supply voltage.

13. The delay circuit of claim 11, wherein the output circuit comprises:
an inverter comprising an input end coupled to the second end the first transistor for receiving the first delayed signal and an output end;
a first NAND gate comprising a first input end coupled to the output end of the inverter, a second input end, and an output end;
a second NAND gate comprising a first input end coupled to the second end of the second transistor for receiving the second delayed signal, a second input end coupled to the output end of the first NAND gate, and an output end coupled to the second input end of the first NAND gate;
an AND gate comprising a first input end coupled to the second end of the second transistor for receiving the second delayed signal, a second input end coupled to the output end of the second NAND gate, and an output end; and
an OR gate comprising a first input end coupled to the output end of the AND gate, a second input end coupled to the second end of the first transistor for receiving the first delayed signal, and an output end for outputting the logic output signal.

14. The delay circuit of claim 13, wherein the output circuit further comprises:
at least one buffer coupled between the second end of the first transistor and the second input end of the OR gate.

15. The delay circuit of claim 13, wherein the output circuit further comprises:
at least one buffer coupled between the second end of the second transistor and the first input end of the AND gate.

16. The delay circuit of claim 11, wherein the first transistor is an N-channel MOS field effect transistor, an N-channel junction field effect transistor, or an NPN bipolar junction transistor.

17. The delay circuit of claim 11, wherein the second transistor is a P-channel MOS field effect transistor, a P-channel junction field effect transistor, or a PNP bipolar junction transistor.

18. The delay circuit of claim 11, wherein the signal processing circuit outputs the first delayed signal having high-level voltage and the second delayed signal having high-level voltage when the voltage signal is less than a first transition voltage, the signal processing circuit outputs the first delayed signal having low-level voltage and the second delayed signal having low-level voltage when the voltage signal is greater than a second transition voltage, and the signal processing circuit outputs the first delayed signal having low-level voltage and the second delayed signal having high-level voltage when the voltage signal is falling into a voltage range between the first transition voltage and the second transition voltage.

19. The delay circuit of claim 18, wherein the first transition voltage is a summation of the second supply voltage and a threshold voltage of the first transistor.

20. The delay circuit of claim 18, wherein the second transition voltage is a difference of the first supply voltage and a threshold voltage of the second transistor.

21. The delay circuit of claim 11, wherein the second supply voltage is a ground voltage.
